(19) United States
(12) Patent Application Publication
(10) Pub. No.: US 2020/0225532 A1
(43) Pub. Date: Jul. 16, 2020

(54) DISPLAYS

(71) Applicant: Radiant Choice Limited, The Valley (AI)

(72) Inventors: Nguyen The Tran, Anaheim, CA (US); Jiun-Pyng You, Irvine, CA (US)

(21) Appl. No.: 16/830,456

(22) Filed: Mar. 26, 2020

Related U.S. Application Data
(63) Continuation-in-part of application No. 16/244,527, filed on Jan. 10, 2019, now Pat. No. 10,642,091.
(60) Provisional application No. 62/626,158, filed on Feb. 5, 2018.

(51) Int. Cl. G02F 1/1335; G02F 1/13357; H01L 27/32

(52) U.S. Cl. CPC G02F 1/133514; H01L 27/3232; G02F 1/133609; G02F 1/133603

(57) ABSTRACT

A display device includes an LCD panel comprising blue color filters, green color filters and red color filters, and a light source for providing light to the LCD panel. The light has a spectrum with first, second and third components. The first component has at least one peak wavelength in a first wavelength range from about 480.1 nm to about 510 nm. The second component has a second wavelength range that is perceived as a green color. The third component has a third wavelength range that is perceived as a red or orange-red color by human eyes. The green color filters are adapted such that they do not transmit the first component of light or transmit a minimal amount of the first component of light so as to prevent a distortion or shift of a CIE coordinate of a filtered green light by the first component of light.

### CROSS-REFERENCE TO RELATED PATENT APPLICATIONS

This application is a continuation-in-part application of U.S. patent application Ser. No. 16/244,527, Jan. 10, 2019, now allowed, which claims priority to and the benefit of U.S. Provisional Patent Application Ser. No 62/626,158, filed Feb. 5, 2018, which are incorporated herein by reference in their entireties.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference is individually incorporated by reference.

### FIELD

The present disclosure relates generally to displays, and more particularly to displays with long blue wavelength and modified color filters.

### BACKGROUND

The background description provided herein is for the purpose of generally presenting the context of the present disclosure. The subject matter discussed in the background of the invention section should not be assumed to be prior art merely as a result of its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the present disclosure.

Digital displays have become inseparable part of our human activity. The displays can be outdoor and indoor large/small displays, televisions (TVs), handheld displays, backlighting based displays, self-emitting displays, and reflective displays. The displays can be source-based displays such as light-emitting diode (LED), organic light-emitting diode (OLED), quantum dot (QD), and laser. They can be passive or active emission devices.

Currently, source-based displays use a white light with short blue wavelength with wavelength peak ranging between 440 nm to 460 nm. There are two reasons for this. One reason is that excitation wavelength of most wavelength conversion materials are limited up to or maximized at this value. Another reason is that green color filters can transmit a significant amount of blue light with wavelength up to 470 nm. This results in low color gamut for blue light with its peak wavelength falling into a wavelength range above 465 nm or 470 nm. Short blue wavelength in digital displays may cause tiredness related to eyestrains after a prolonged and frequent use of digital devices. This may lower work productivity.

Therefore, a heretofore unaddressed need exists in the art to address the aforementioned deficiencies and inadequacies.

### SUMMARY

The invention, in one aspect, relates to a light source for provide light having a spectrum with a first component, a second component and a third component, for a display device. The light source includes at least one light emitting chip including at least one of light-emitting diode (LED) chips, laser diode (LD) chips, and organic LED (OLED) chips. At least one of the first, second and third light components is emitted from the at least one light emitting chip. The first component of the light spectrum being emitted from the at least one light emitting chip has at least one peak wavelength in a first wavelength range from about 480.1 nm to about 510 nm. The second component has a second wavelength range that is perceived as a green color. The third component has a third wavelength range that is perceived as a red or orange-red color by human eyes.

As used herein, the terms: the first component, the second component and the third component of the light also refer to a blue light component, a green light component and a red light component of the light, respectively.

In another aspect, the invention relates to a display device. The display device comprises a liquid crystal display (LCD) panel comprising a plurality of blue color filters, a plurality of green color filters, and a plurality of red color filters; and a light source configured to provide light to the LCD panel. The light has a spectrum with a first component, a second component and a third component. The first component has at least one peak wavelength in a first wavelength range from about 480.1 nm to about 510 nm.

The second component has a second wavelength range that is perceived as a green color. The third component has a third wavelength range that is perceived as a red or orange-red color by human eyes. The plurality of green color filters is adapted such that they do not transmit the first component of light or transmit a minimal amount of the first component of light so as to prevent a distortion or shift of a CIE (International Commission on Illumination) coordinate of a filtered green light by the first component of light.

In certain embodiments, each of the plurality of green color filters has a transmission of less than or equal to about 5% at a wavelength of about 490 nm, about 10% at a wavelength of about 495 nm, about 30% at a wavelength of about 500 nm, and about 50% at a wavelength of about 510 nm.

In certain embodiments, the transmitted minimal amount of the first component of light is about 10% or less of the first component of light.

In yet another aspect, the invention relates to a display device comprising an LCD panel comprising a color filter layer having a plurality of blue color filters, a plurality of green color filters and a plurality of red color filters, and a green purifying layer disposed on at least one side of the color filter layer, and a light source configured to provide light to the LCD panel. The green purifying layer is adapted for removing/blocking undesired colors including blue, orange, and/or red colors. The light has a spectrum with a first component, a second component and a third component. The first component has at least one peak wavelength in a first wavelength range from about 480.1 nm to about 510 nm. The second component has a second wavelength range that is perceived as a green color. The third component has a third wavelength range that is perceived as a red or orange-red color by human eyes.

In certain embodiments, the green purifying layer is configured such that it only removes or blocking the undesired colors that enter and pass through the plurality of green color filters.

In certain embodiments, the green purifying layer comprises light correcting materials or structures that are only positioned in areas directly above or underneath the plurality of green color filters and are not presented in areas directly above or underneath the plurality of blue filters and the plurality of red color filters.

In certain embodiments, the light source comprises at least one light emitting chip including at least one of LED chips, LD chips, and OLED chips.

The invention, in one aspect, relates to a display. The display includes an LCD panel including a plurality of blue color filters, a plurality of green color filters, and a plurality of red color filters; and a light source configured to provide light to the LCD panel, wherein the light has a spectrum with a blue component, a green component and a red component. The blue component has at least one peak wavelength in between about 465 nm to about 495 nm.

In one embodiment, the blue component has intensity of a peak at a longer wavelength being higher than that at a shorter wavelength.

In one embodiment, the light source includes at least one of blue LED chips, blue LD chips, and blue OLED chips for emitting the blue component. Alternatively, the light source includes at least one of blue LED chips, blue LD chips, and blue OLED chips for emitting the blue component, and of green LED chips, green LD chips, and green OLED chips for emitting the green component.

In one embodiment, the light source further includes green and red wavelength conversion materials for emitting the green component and the red component when excited by the blue component. Alternatively, the light source further includes red wavelength conversion materials for emitting the red component when excited by the blue component and/or the green component.

In one embodiment, the wavelength conversion materials include at least one of phosphor materials, quantum dot materials, dye materials.

In one embodiment, the light source is a backlight unit.

In one embodiment, the plurality of green color filters has a transmission cut off wavelength being about 480 nm or greater than about 480 nm.

In one embodiment, the plurality of blue color filters has a transmission cut off wavelength being no greater than about 515 nm.

In yet another aspect, the invention relates to a display device. The display device includes an LCD panel including a plurality of blue color filters, a plurality of green color filters, and a plurality of red color filters; and a light source configured to provide light to the LCD panel, wherein the light has a spectrum with a blue component, a green component and a red component. The blue component has an intensity being broadly distributed over a wavelength range of about 430 nm to about 495 nm.

In one embodiment, the blue component has a peak ranging from about 470 nm to about 510 nm.

In one embodiment, the light source includes at least one of blue LED chips, blue LD chips, and blue OLED chips for emitting the blue component. Alternatively, the light source includes at least one of blue LED chips, blue LD chips, and blue OLED chips for emitting the blue component, and of green LED chips, green LD chips, and green OLED chips for emitting the green component.

In one embodiment, the light source further includes green and red wavelength conversion materials for emitting the green component and the red component when excited by the blue component. Alternatively, the light source further includes red wavelength conversion materials for emitting the red component when excited by the blue component and/or the green component.

In one embodiment, the wavelength conversion materials include at least one of phosphor materials, quantum dot materials, dye materials.

In one embodiment, the light source is a backlight unit.

In one embodiment, the plurality of green color filters has a transmission cut off wavelength being about 480 nm or greater than about 480 nm.

In one embodiment, the plurality of blue color filters has a transmission cut off wavelength being no greater than about 515 nm.

In yet another aspect, the invention relates to a light source for provide light having a spectrum with a blue component, a green component and a red component, for a display device. The light source includes at least one of blue LED chips, blue LD chips, and blue OLED chips for emitting the blue component; and green and red wavelength conversion materials for emitting the green component and the red component when excited by the blue component. The blue component has at least one peak wavelength in between about 465 nm to about 510 nm, and intensity of a peak at a longer wavelength being higher than that at a shorter wavelength. The blue component has an intensity being broadly distributed over a wavelength range of about 430 nm to about 495 nm, and a peak ranging from about 470 nm to about 490 nm.

In one embodiment, the wavelength conversion materials include at least one of phosphor materials, quantum dot materials, dye materials.

In yet another aspect, the invention relates to a light source for provide light having a spectrum with a blue component, a green component and a red component, for a display device. The light source includes at least one of blue LED chips, blue LD chips, and blue OLED chips for emitting the blue component, and of green LED chips, green LD chips, and green OLED chips for emitting the green component; and red wavelength conversion materials for emitting the red component when excited by the blue component and the blue component. The blue component has at least one peak wavelength ranging from about 465 nm to about 510 nm, and intensity of a peak at a longer wavelength being higher than that at a shorter wavelength. The blue component has an intensity being broadly distributed over a wavelength range of about 430 nm to about 495 nm, and a peak ranging from about 470 nm to about 490 nm.

In one embodiment, the wavelength conversion materials include at least one of phosphor materials, quantum dot materials, dye materials.

In a further aspect, the invention relates to a display device comprising a substrate, an electrode layer disposed on the substrate, an emissive layer disposed on the electrode layer, a glass film disposed on the emissive layer, and a polarizer film disposed on the glass film or between the emissive layer and the glass film. The emissive layer comprises light sources that form a matrix of pixels, each pixel comprising subpixels.

In one embodiment, each light source at least one light emitting chip including at least one of LED chips, LD chips, and OLED chips.

In one embodiment, each pixel contains a light source that provides at least three light components including blue, green, and red light components.

In one embodiment, each pixel contains at least three subpixels with each subpixel having one of a light source that provides one of blue, green, and red light.

In one embodiment, the blue component of the light source has a wavelength ranging from about 430 nm to about 510 nm, with its peak wavelength ranging from about 470 nm to about 500 nm.

In one embodiment, the blue component of the light source has a wavelength ranging from 430 nm to 510 nm, with at least one peak wavelength ranging from about 430 nm to about 470 nm and one peak wavelength ranging from about 470 nm to about 500 nm.

In one embodiment, each pixel contains four subpixels with each subpixel having one of the light sources that provides one of dark blue, light blue, green, and red light. In one embodiment, the light blue light source has its peak wavelength ranging from about 470 nm to about 500 nm.

These and other aspects of the invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment.

FIG. 1A is a schematic of a display device according to one embodiment of the invention.

FIG. 1B is a schematic of a display device according to another embodiment of the invention.

FIG. 1C is a schematic of a display device according to yet another embodiment of the invention.

FIG. 2 is a diagram illustrating wavelength spectrum of a conventional light spectrum with shorter blue wavelength, wavelength spectrum of a light source with longer blue wavelength according to one embodiment of the invention, and wavelength spectrum of a light source with multiple peaks of blue wavelength to spread out the blue intensity according to another embodiment of the invention.

FIG. 3 is a diagram illustrating the transmission spectra of conventional green, blue and red color filters.

FIG. 4 is a diagram illustrating green color filters with different transmission spectra according to embodiments of the invention.

FIG. 5 is a diagram illustrating the NTSC gamut ratio and gamut coverage of a conventional system and the proposed system according to one embodiment of the invention.

FIG. 6 is a diagram illustrating color gamut charts for different white light spectra and color filters to show color gamut area of proposed systems and conventional systems: (1) with a conventional short blue wavelength, and (2) with shifted blue wavelength and with broad distributed blue wavelength.

FIG. 7 is a diagram illustrating a NTSC gamut ratio and gamut coverage as well as Rec. 2020 gamut coverage of different color filters with different types of blue light.

FIG. 8 is a schematic of a display device according to one embodiment of the invention.

### DETAILED DESCRIPTION

The disclosure will now be described more fully hereinafter with reference to the accompanying drawings, in which exemplary embodiments of the disclosure are shown. This invention may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting and/or capital letters has no influence on the scope and meaning of a term; the scope and meaning of a term are the same, in the same context, whether or not it is highlighted and/or in capital letters. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only and in no way limits the scope and meaning of the disclosure or of any exemplified term. Likewise, the disclosure is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below can be termed a second element, component, region, layer or section without departing from the teachings of the disclosure.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present.

It will also be appreciated by those of skill in the art that references to a structure or feature that is disposed “adjacent” to another feature may have portions that overlap or underlie the adjacent feature.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top”, may be used herein to describe one element's relationship to another element as illustrated in the figures. It will be understood that relative terms are intended to encompass different orientations of the device in addition to the orientation shown in the figures. For example, if the device in one of the figures is turned over, elements described as being on the “lower” side of other elements would then be oriented on the “upper” sides of the other elements. The exemplary term “lower” can, therefore, encompass both an orientation of lower and upper, depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the phrase “at least one of A, B, and C” should be construed to mean a logical (A or B or C), using a non-exclusive logical OR. As used herein, the term “and/or” includes any and all combinations of one or more of the associated listed items.

Typically, terms such as “about,” “approximately,” “generally,” “substantially,” and the like unless otherwise indicated mean within 20 percent, preferably within 10 percent, preferably within 5 percent, and even more preferably within 3 percent of a given value or range. Numerical quantities given herein are approximate, meaning that the term “about,” “approximately,” “generally,” or “substantially” can be inferred if not expressly stated.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in different order (or concurrently) without altering the principles of the invention.

The invention, in one aspect, relates to a light source for provide light having a spectrum with a first component, a second component and a third component, for a display device. The light source includes at least one light emitting chip including at least one of light-emitting diode (LED) chips, laser diode (LD) chips, and organic LED (OLED) chips. At least one of the first, second and third light components is emitted from the at least one light emitting chip. The first component of the light spectrum being emitted from the at least one light emitting chip has at least one peak wavelength in a first wavelength range from about 480.1 nm to about 510 nm. The second component has a second wavelength range that is perceived as a green color. The third component has a third wavelength range that is perceived as a red or orange-red color by human eyes.

In another aspect, the invention relates to a display device. The display device comprises a liquid crystal display (LCD) panel comprising a plurality of blue color filters, a plurality of green color filters, and a plurality of red color filters; and a light source configured to provide light to the LCD panel. The light has a spectrum with a first component, a second component and a third component. The first component has at least one peak wavelength in a first wavelength range from about 480.1 nm to about 510 nm. The second component has a second wavelength range that is perceived as a green color. The third component has a third wavelength range that is perceived as a red or orange-red color by human eyes. The plurality of green color filters is adapted such that they do not transmit the first component of light or transmit a minimal amount of the first component of light so as to prevent a distortion or shift of a CIE (International Commission on Illumination) coordinate of a filtered green light by the first component of light.

In certain embodiments, each of the plurality of green color filters has a transmission of less than or equal to about 5% at a wavelength of about 490 nm, about 10% at a wavelength of about 495 nm, about 30% at a wavelength of about 500 nm, and about 50% at a wavelength of about 510 nm.

In certain embodiments, the transmitted minimal amount of the first component of light is about 10% or less of the first component of light.

In yet another aspect, the invention relates to a display device comprising an LCD panel comprising a color filter layer having a plurality of blue color filters, a plurality of green color filters and a plurality of red color filters, and a green purifying layer disposed on at least one side of the color filter layer, and a light source configured to provide light to the LCD panel. The green purifying layer is adapted for removing/blocking undesired colors including blue, orange, and/or red colors. The light has a spectrum with a first component, a second component and a third component. The first component has at least one peak wavelength in a first wavelength range from about 480.1 nm to about 510 nm. The second component has a second wavelength range that is perceived as a green color. The third component has a third wavelength range that is perceived as a red or orange-red color by human eyes.

In certain embodiments, the green purifying layer is configured such that it only removes or blocking the undesired colors that enter and pass through the plurality of green color filters.

In certain embodiments, the green purifying layer comprises light correcting materials or structures that are only positioned in areas directly above or underneath the plurality of green color filters and are not presented in areas directly above or underneath the plurality of blue filters and the plurality of red color filters.

In certain embodiments, the light source comprises at least one light emitting chip including at least one of LED chips, LD chips, and OLED chips.

As described below, the terms: the first component, the second component and the third component of the light also refer to a blue light component, a green light component and a red light component of the light, respectively.

According to the invention, a display (e.g., a digital display) contains a light source having blue light component with its peak wavelength ranging above 465 nm and a green color filter with insignificant transmission of blue light of the proposed light source so that a wide color gamut can be obtained with the proposed light source. The digital display has a light emitting source that is configured to provide light for the display. The light emitting sources can be light emitting chips such as LED chips and LD chips, or OLED devices, and/or wavelength conversion materials. The light from different light emitting sources can be combined to generate different color of light including white light, depending on intensity level of each source.

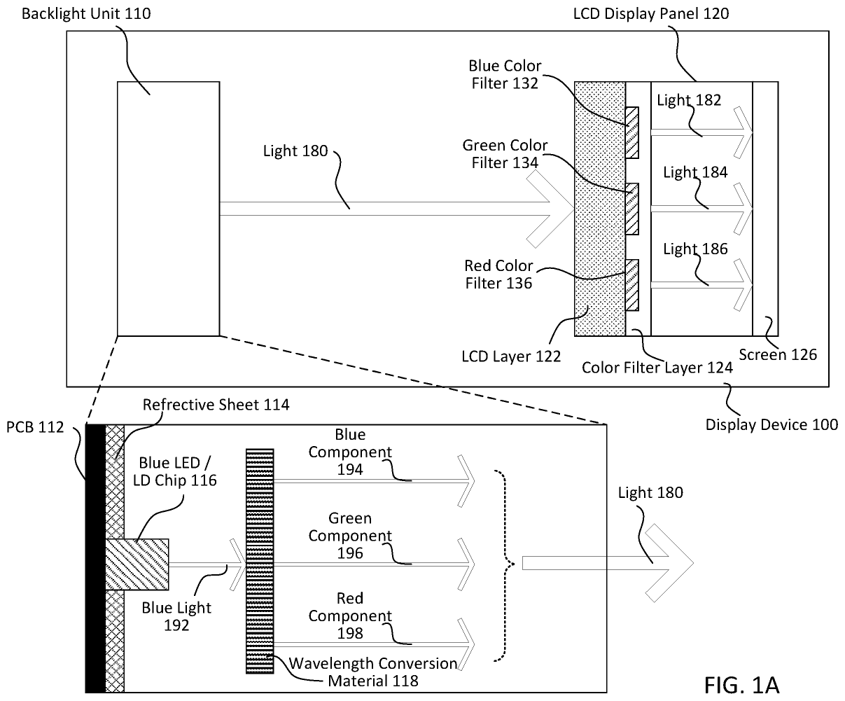

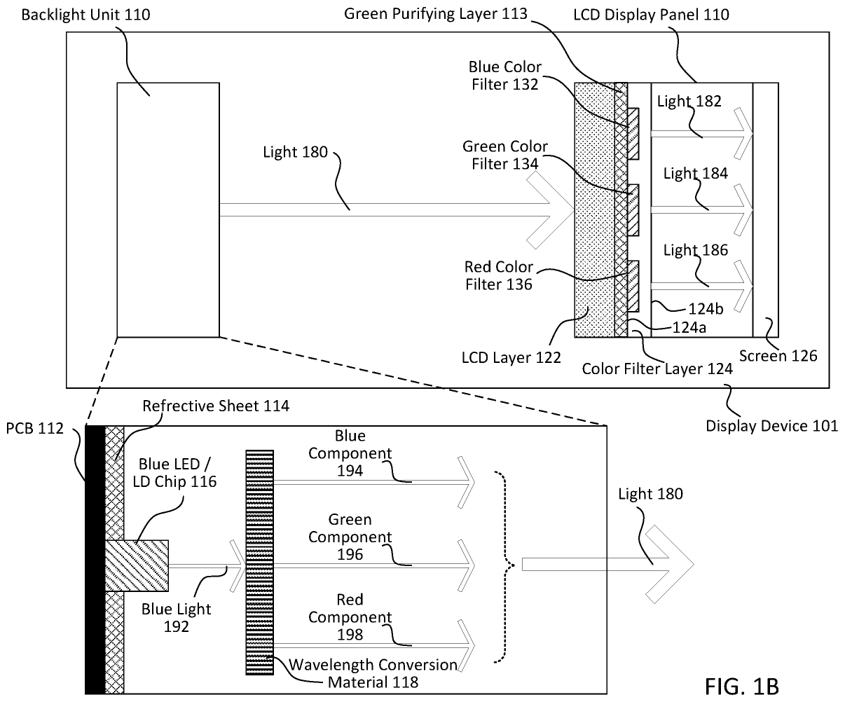

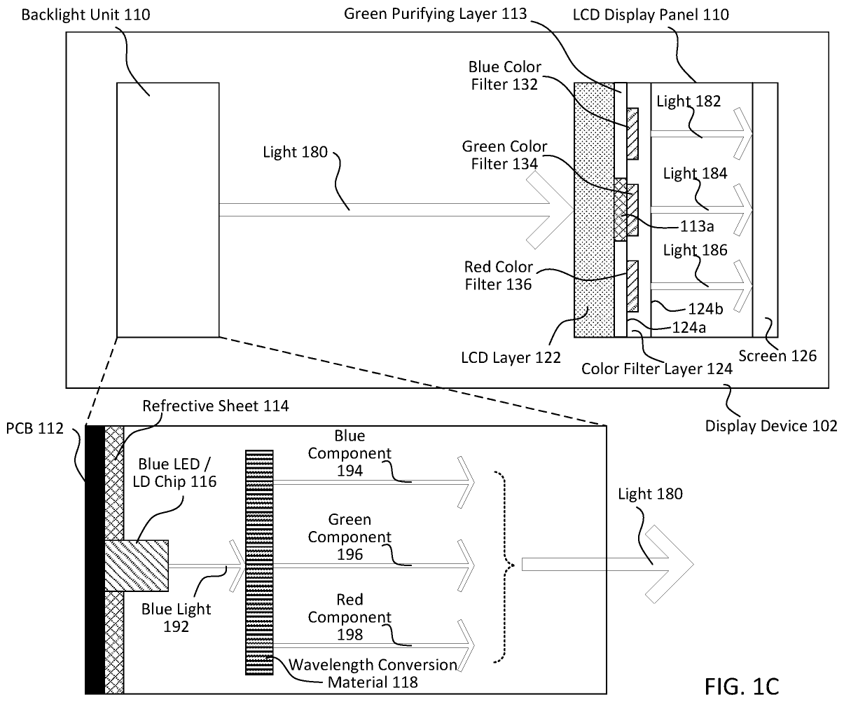

FIG. 1A is a schematic of a display device 100 according to one embodiment of the invention. The display device 100 has a light source (e.g., a backlight unit 110) and a LCD display panel 120.

It should be noted that the backlight unit 110 can be achieved by many different ways. As shown in FIG. 1A, one example of the backlight unit 110 has a printed circuit board (PCB) 112, a reflective sheet 114, a blue LED or LD chip 116, a wavelength conversion material 118. The blue LED or LD chip 116 is placed on the PCB 112, and the reflective sheet 114 is also placed on the PCB 112. The reflective sheet 114 has holes defined corresponding to the location of the blue LED or LD chip 116, and is placed on the PCB 112 such that the blue LED or LD chip 116 is disposed in the holes of the reflective sheet 114. The blue LED or LD chip 116 emits blue light 192, and the blue light 192 passes through the wavelength conversion material 118. The wavelength conversion material 118 is excited by the blue light 192 emitted from the blue LED or LD chip 116, and may emit light with different wavelength (e.g., green light and red light). For example, after passing through the wavelength conversion material 118, the blue light 192 becomes light 180 which has three components: the blue component 194, the green component 196, and the red component 198.

The wavelength conversion material 118 may be any of phosphor materials and quantum dot (QD) materials that can be excited by the blue light 192 emitted from the blue LED or LD chip 116 and emits at least one of the green component 196 and the red component 198. In certain embodiments, there may be more than one of the wavelength conversion material 118. For example, one wavelength conversion material emits a green component 196 and another wavelength conversion material emits a red component 198.

In certain embodiments, the wavelength conversion material 118 may be coated on the blue LED or LD chip 116.

In certain embodiments, the wavelength conversion material 118 may be in remote configuration of the wavelength conversion structure as shown in FIG. 1A.

As stated above, there may be other ways to achieve the backlight unit 110. In certain embodiments, the backlight unit 110 may have at least one blue LED/LD chip 116, at least one green LED/LD chip, and at least one red wavelength conversion material. The red wavelength conversion material can be excited by light emitted from the blue LED/LD chip 116 and the green LED/LD chip. In other words, the light 180 has three components: the blue component 194, the green component 196 and the red component 198, while the red component 198 is emitted from the red wavelength conversion material.

In certain embodiments, the backlight unit 110 has at least one blue LED/LD chip, at least on green LED/LD chip, and at least one red LED/LD chip. In other words, the light 180 has three components: the blue component 194, the green component 196 and the red component 198, while none of them are emitted from wavelength conversion material.

In certain embodiments, the backlight unit 110 has at least one violet or purple LED/LD chip. The wavelength conversion material can be any of phosphor materials and QD materials that can be excited by the light emitted from the violet or purple LED/LD chip and emits at least one of blue, green and red wavelength spectrum (i.e., at least one of blue component 194, green component 196 and red component 198). In certain embodiments, the blue wavelength spectrum can have a broad distribution of intensity to reduce eyestrain.

FIG. 1B is a schematic of a display device 101 according to another embodiment of the invention. The display device 101 is the same as the display device 100 shown in FIG. 1A, except that a green purifying layer 113 is provided at least on one side of the color filter layer 124 to remove undesired blue and/or orange color. In the exemplary embodiment shown in FIG. 1B, the green purifying layer 113 is disposed between the LCD layer 122 and the color filter layer 124, i.e., on the light input side 124a of the color filter layer 124. In other embodiments, the green purifying layer 113 can be disposed on the light output side 124b of the color filter layer 124, or on both the light input side 124a and the light output side 124b of the color filter layer 124 (not shown). The green purifying layer 113 is configured in a manner such that it only removes blue and/or orange and/or red color that enter and pass through the green color filter 134.

FIG. 1C is a schematic of a display device 102 according to yet another embodiment of the invention. The display device 102 is the same as the display device 101 shown in FIG. 1B, except that the green purifying layer 113 contains light correcting materials or structures 113a that are only directly on above or below the green color filter 134 and are not present in the area directly above or below the blue filter 132 and the red color filter 136. In this exemplary embodiment shown in FIG. 1C, the light correcting materials or structures 113a of the green purifying layer 113 is directly disposed below the green color filter 134, i.e., on the light input side 124a of the color filter layer 124. In other embodiments, the light correcting materials or structures 113a of the green purifying layer 113 can be disposed directly above the green color filter 134, i.e., the light output side 124b of the color filter layer 124, or on both the light input side 124a and the light output side 124b of the color filter layer 124 (not shown).

Conventional light spectrum has short blue wavelengths. However, the light source (e.g., the backlight unit 110) of the current invention can be constructed with a blue wavelength peak shifted to a longer wavelength range or spreading intensity of the blue wavelength while maintaining high color quality of the light source (e.g., the backlight unit 110).

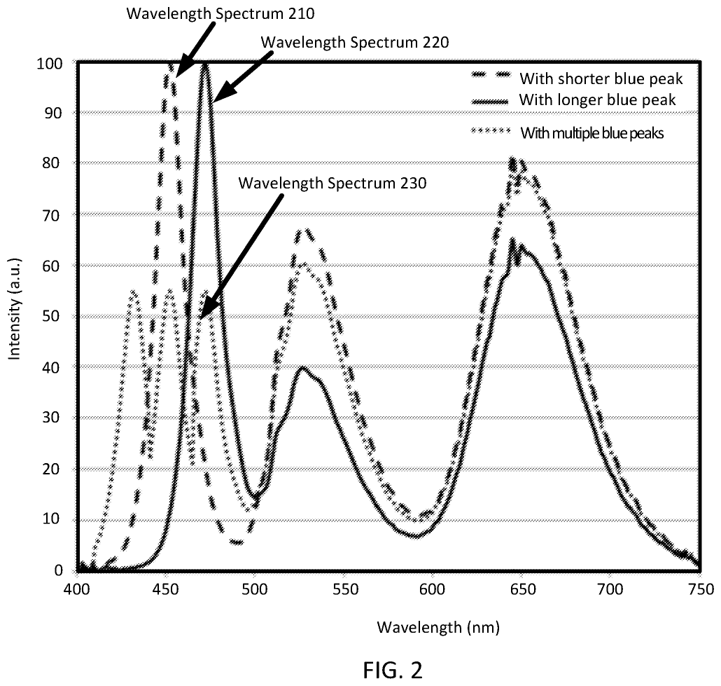

FIG. 2 shows examples of a wavelength spectrum of a conventional light spectrum with shorter blue wavelengths, a wavelength spectrum of a light source (e.g., the backlight unit 110) with longer blue wavelengths according to one embodiment of the invention, and a wavelength spectrum of a light source with multiple peaks of blue wavelength to spread out the blue intensity according to another embodiment of the invention. The wavelength range of FIG. 2 is from about 400 nm to about 750 nm.

The wavelength spectrum 210, illustrated by a dash line in FIG. 2, is a wavelength spectrum of a conventional light spectrum with shorter blue wavelengths. As mentioned above, the wavelength peak ranges between about 440 nm to about 460 nm. On the other hand, the wavelength spectrum 220, illustrated by a solid line in FIG. 2, is a wavelength spectrum of a light source with longer blue wavelengths according to one embodiment of the invention. The light source can provide the light spectrum that contains a blue component of a shifted blue peak wavelength with its peak ranging from about 465 nm to about 500 nm. In other words, the light source with longer blue wavelengths according to one embodiment of the invention has a shifted blue wavelength peak to a longer wavelength range, i.e., shifted from about 440˜460 nm to about 465˜500 nm, compared to the wavelength spectrum 210.

In certain embodiments, the blue component of the light source has wavelengths ranging from about 430 nm to about 510 nm, with its peak wavelength ranging from about 470 nm to about 500 nm. And the intensity or amount of the shorter blue wavelength (i.e., shorter than 455 nm) is very small compared to the longer blue wavelength. In other words, the intensity of the blue component with the longer blue wavelengths is stronger than that with the shorter blue wavelengths.

In certain embodiments, preferably, the blue component of the light source has wavelengths ranging from about 450 nm to about 510 nm, with its peak wavelength ranging from about 470 nm to about 500 nm. And the intensity or amount of shorter blue wavelength (i.e., shorter than about 455 nm) is very small compared to the longer blue wavelength. In other words, the intensity of the blue component with the longer blue wavelengths is stronger than that with the shorter blue wavelengths.

Moreover, the wavelength spectrum 230, illustrated by another dash line in FIG. 2, is a wavelength spectrum of a light source with multiple peaks of blue wavelengths to spread out the blue intensity. For example, the wavelength spectrum 230 has three peaks as illustrated in FIG. 2. It should be noted that other number of peaks (e.g., five peaks) can also be employed. As the wavelength spectrum 230 has multiple peaks of the blue wavelength, the blue component intensity is spread out. For example, the peaks of the wavelength spectrum 230 have intensities lower than 60 a.u. as shown in FIG. 2.

More specifically, in certain embodiments, the blue LED/LD chip 116 emits light with its peak ranging from about 465 nm to about 500 nm. In certain embodiments, a plurality of blue LED/LD chips 116 emit light with a plurality of peaks at wavelengths ranging from about 430 nm to about 500 nm, and the peak with a longest wavelength has a higher intensity than the peak with a shorter wavelength. In certain embodiments, the blue LED/LD chip(s) 116 emits light with a broad bandwidth in the blue wavelength range of the spectrum.

In liquid crystal display (LCD), color filters such as blue, green and red color filters are required to make blue, green and red color pixels, respectively. Currently, green color filter transmits significant amounts of blue wavelengths down to about 465 nm. This results in the CIE coordinate (i.e., CIE 1931 color spaces) of the green pixel being shifted toward a cyan region, when the light source contains a large portion of blue wavelength energy that can be transmitted through the green color filter.

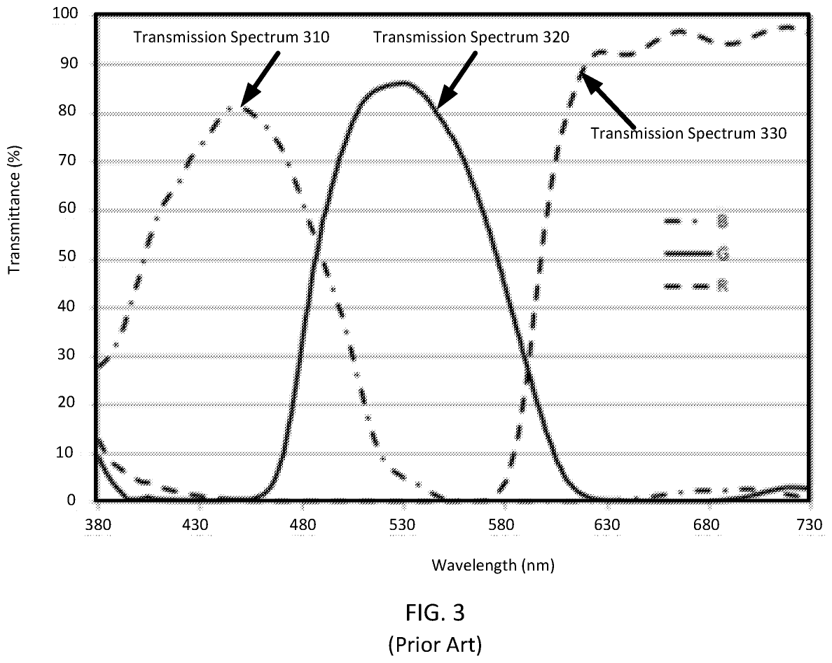

FIG. 3 shows the transmission spectra of a conventional green color filter as well as blue and red color filters. As shown in FIG. 3, the transmission spectrum 310 is that of a conventional blue color filter, the transmission spectrum 320 is that of a conventional green color filter, and the transmission spectrum 330 is that of a conventional red color filter. The transmission spectrum 310 has a high transmittance in the blue wavelength region, the transmission spectrum 320 has a high transmittance in the green wavelength region, and the transmission spectrum 330 has a high transmittance in the red wavelength region. As shown in FIG. 3, the conventional green color filter transmits up to 4%, 10% and 20% of the blue light at wavelength of about 465 nm, about 470 nm and about 475 nm, respectively. As mentioned above, the results in the CIE coordinate of the green pixel being shifted toward cyan region. Therefore, it is desirable to tune the green color filter such that the green color filter can block blue wavelengths to reduce interference of the blue wavelengths on the green pixels. In other words, the green color filter 134 needs to be tuned to remove the blue wavelengths from the green color pixel to improve the gamut area of the display device 100 or 101.

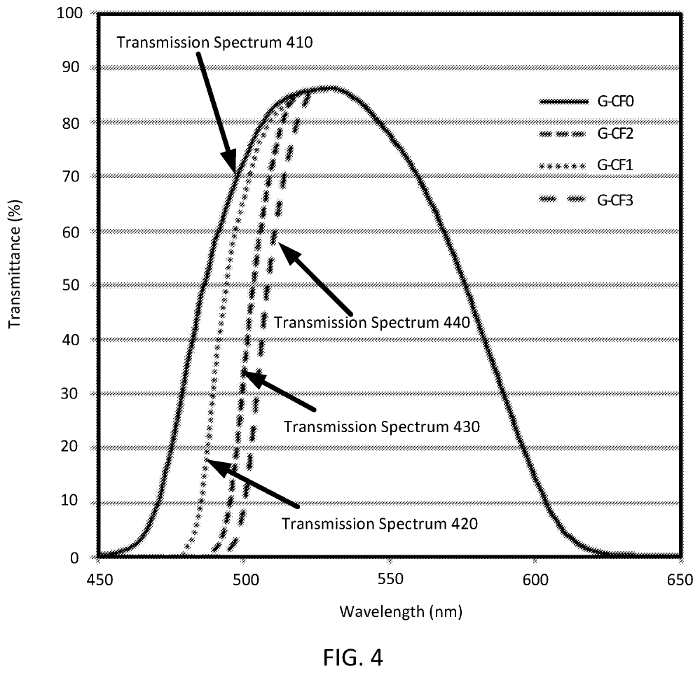

FIG. 4 shows green color filters with different transmission spectra according to embodiments of the invention. The transmission spectrum 410 is that of a green color filter G-CF0 which is a conventional green color filter, the transmission spectrum 420 is that of a green color filter G-CF1, the transmission spectrum 430 is that of a green color filter G-CF2, and the transmission spectrum 440 is that of a green color filter G-CF3. Compared to the transmission spectrum 410 of the green color filter G-CF0, the transmission spectra 420, 430 and 440 of the improved green color filters 134 (i.e., G-CF1, G-CF2 and G-CF3) are cut off at about 480 nm, about 490 nm and about 495 nm. In other words, the improved green color filters 134 (i.e., G-CF1, G-CF2 and G-CF3), reflected by transmission spectra 420, 430 and 440, block more blue wavelength of the light source (e.g., the backlight unit 110).

In certain embodiments, the transmittance of the green color filter 134 is below about 25%, about 20%, about 15%, about 10% and about 5% at the wavelength shorter than about 480 nm. In certain embodiments, the transmittance of the green color filter 134 is below about 25%, about 20%, about 15%, about 10% and about 5% at the wavelength shorter than about 485 nm. In certain embodiments, the transmittance of the green color filter 134 is below about 25%, about 20%, about 15%, about 10% and about 5% at the wavelength shorter than about 490 nm. In certain embodiments, the transmittance of the green color filter is below about 25%, about 20%, about 15%, about 10% and about 5% at the wavelength shorter than about 495 nm. In certain embodiments, the transmittance of the green color filter is below about 25%, about 20%, about 15%, about 10% and about 5% at the wavelength shorter than about 500 nm.

In certain embodiments, the blue color filter 132 can be tuned such that it can block green wavelengths to reduce interference of the green wavelengths on the blue pixels. In certain embodiments, the transmittance of the blue color filter 132 is below about 25%, about 20%, about 15%, about 10% and about 5% at the wavelength longer than about 500 nm. In certain embodiments, the transmittance of the blue color filter 132 is below about 25%, about 20%, about 15%, about 10% and about 5% at the wavelength longer than about 505 nm. In certain embodiments, the transmittance of the blue color filter 132 is below about 20%, about 15%, about 10% and about 5% at the wavelength longer than about 510 nm.

In certain embodiments, a green purifying layer is at least on one side of the color filter layer to remove undesired blue and/or orange color. In one exemplary embodiment shown in FIG. 1B, the green purifying layer 123 is disposed between the LCD layer 122 and the color filter layer 124, i.e., on the light input side 124a of the color filter layer 124. In other embodiments, the green purifying layer 123 can also disposed on the light output side 124b of the color filter layer 124, or on both the light input side 124a and the light output side 124b of the color filter layer 124 (not shown). The green purifying layer 123 is configured in a manner such that it only removes blue and/or orange and/or red color that enter and pass through the green color filter 134. In certain embodiments, the green purifying layer 123 contains light correcting materials or structures that are only directly on top or below the green color filter 134 and are not present in the area directly above or below the blue filter 132 and the red color filter 136.

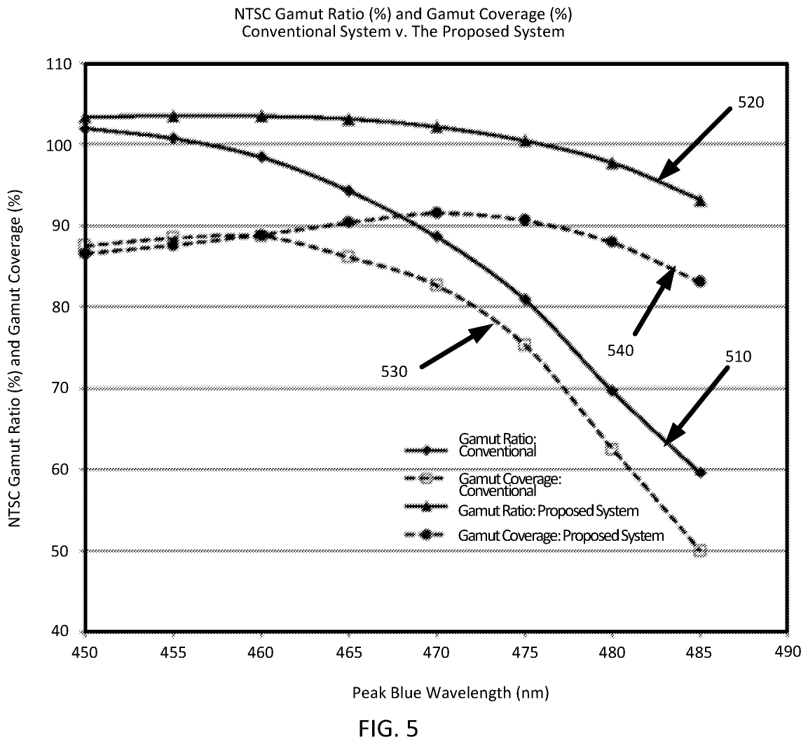

The more the blue wavelengths of the light source are blocked by the green color filter, the higher color gamut area can be achieved with this display device 100 or 101. FIG. 5 shows the NTSC gamut ratio and gamut coverage of a conventional system and the proposed system (e.g., the display device 100 or 101) according to one embodiment of the invention.

The curve 510 is the NTSC gamut ratio of a conventional system, while the curve 520 is the NTSC gamut ration of the invented system (e.g., the display device 100 or 101). Similarly, the curve 530 is the NTSC gamut coverage of a conventional system, while the curve 540 is the NTSC gamut coverage of the inventied system (e.g., the display device 100 or 101). It can be found that by tuning the green color filter 134 with cut off at about 480 nm or higher, the color gamut 520 can be maintained high with different light spectra with different blue light distribution. For example, when the peak blue wavelength is about 485 nm, the conventional system has a NTSC gamut ratio lower than about 60%, while the invented system has a NTSC gamut ratio higher than about 90%. Additionally, as shown in FIG. 5, the invented system of modified color filters provides color gamut less dependent on the peak wavelength of the blue spectrum than the conventional system.

The gamut ratio and gamut coverage, under NTSC and the ITU-R Recommendation BT.2020 (Rec. 2020), for white light spectra with a peak blue wavelength at about 471 nm can be as high as or higher than that for white light spectra with a peak blue wavelength at about 450 nm.

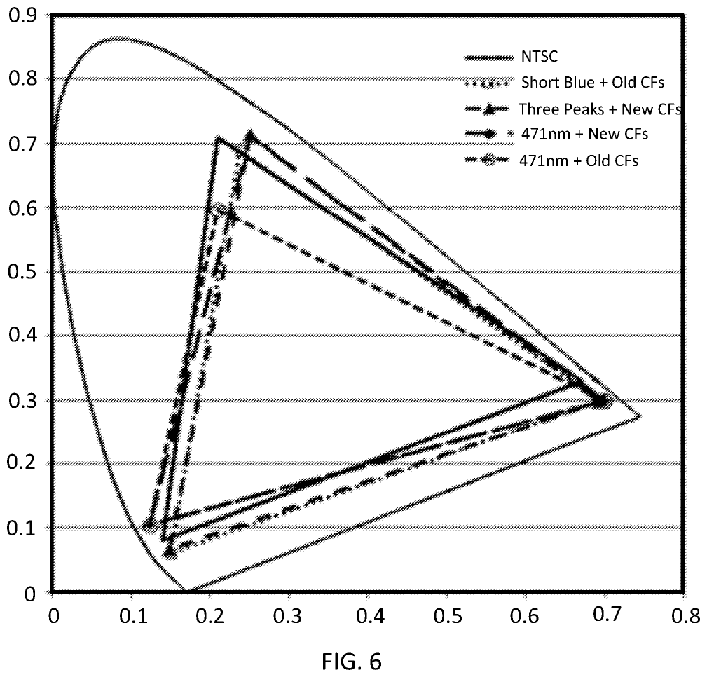

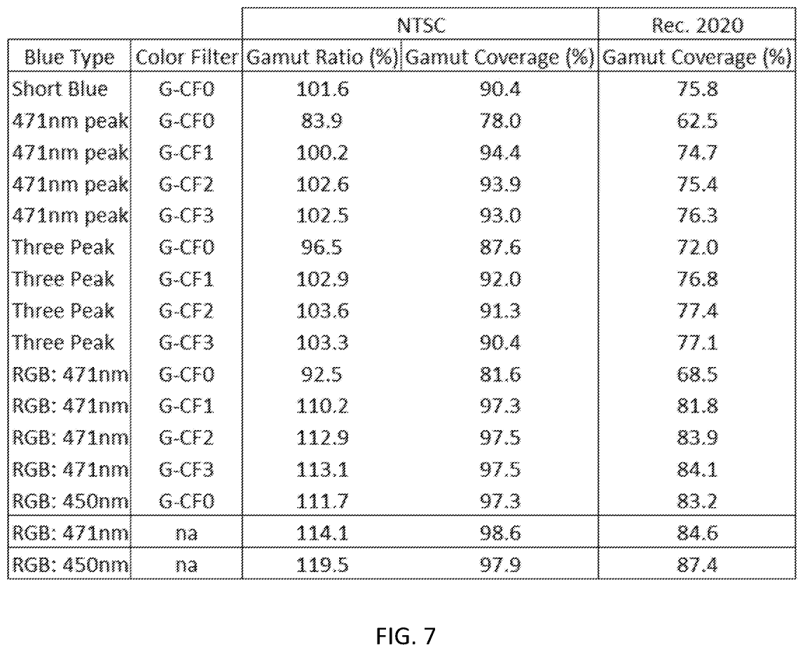

FIG. 6 shows color gamut charts for different white light spectra and color filters: (1) with a conventional short blue wavelength, and (2) with shifted blue wavelength and with broad distributed blue wavelength. As shown in FIG. 6, the system of the invention has a color gamut area being larger than the color gamut area of the conventional system with the blue component of a longer wavelength or peak. FIG. 7 shows a NTSC gamut ratio and gamut coverage as well as Rec. 2020 gamut coverage of different color filters with different types of blue light.

It can be found that using the improved green color filters 134 (i.e., G-CF1, G-CF2 and G-CF3) can improve the gamut ratio and gamut coverage of the display device 100 or 101 under the same conditions. Therefore, with the help of the improved green color filters 134 (i.e., G-CF1, G-CF2 and G-CF3), the light source (e.g., the backlight unit 110) with shifted blue wavelength (e.g., peak blue wavelength at about 471 nm as shown in FIG. 7) and with broad distributed blue wavelength (e.g., three peaks of blue wavelength to spread out the blue intensity) can still achieve as good as or even better gamut ratio and gamut coverage compared to conventional short blue wavelength display. In other words, compared with conventional blue wavelength display, the display device 100 or 101 according to the invention can solve the problem of tiredness by avoiding using a short blue wavelength light source, without the expense of lower gamut ratio and gamut coverage.

In other display devices having RGB sources representing each color pixel (e.g., RGB displays or OLED displays), the blue light spectrum with its peak shifted to about 471 nm can also provide a high color gamut coverage compared to a conventional light spectrum with its blue light peak at about 450 nm. As shown in FIG. 7, for RGB source with blue peak at about 471 nm, the NTSC and Rec. 2020 gamut coverage is about 98.6% and about 84.6%, respectively. For RGB with blue peak at about 450 nm, the NTSC and Rec. 2020 gamut coverage is about 97.9% and about 87.4%, respectively.

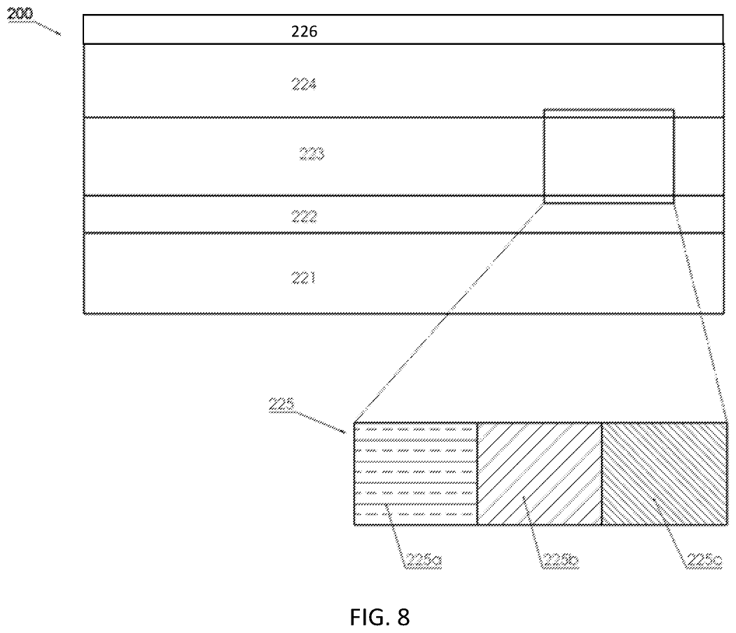

In certain embodiments, as shown in FIG. 8, a display device 200 is an emissive display that has light sources forming emissive pixels or subpixels. The display device 200 has a substrate 221, an electrode layer 222 disposed on the substrate, an emissive layer 223 disposed on the electrode layer 222, a glass film 224 disposed on the emissive layer 223, and a polarizer film 226 disposed on the glass film 224 or between the emissive layer 223 and the glass film 224. The emissive layer 223 comprises light sources that form a matrix of pixels 225, each pixel comprising subpixels 225a, 225b, and 225c. The emissive layer 223 contains light sources that can be LED, micro LED, LD, and organic LED (OLED) and form matrix of pixels 225. Each pixel can contain subpixels 225a, 225b, and 225c.

In one embodiment, each light source has at least one light emitting chip including at least one of LED chips, LD chips, and OLED chips.

In one embodiment, each pixel contains a light source that provides at least three light components including blue, green, and red light components.

In one embodiment, each pixel contains at least three subpixels with each subpixel having one of a light source that provides one of blue, green, and red light.

In one embodiment, the blue component of the light source has a wavelength ranging from about 430 nm to about 510 nm, with its peak wavelength ranging from about 470 nm to about 500 nm.

In one embodiment, the blue component of the light source has a wavelength ranging from 430 nm to 510 nm, with at least one peak wavelength ranging from about 430 nm to about 470 nm and one peak wavelength ranging from about 470 nm to about 500 nm.

In one embodiment, each pixel contains four subpixels with each subpixel having one of the light sources that provides one of dark blue, light blue, green, and red light. In one embodiment, the light blue light source has its peak wavelength ranging from about 470 nm to about 500 nm.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments are chosen and described in order to explain the principles of the disclosure and their practical application so as to activate others skilled in the art to utilize the disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A light source for provide light having a spectrum with a first component, a second component and a third component, for a display device, comprising:
at least one light emitting chip including at least one of light-emitting diode (LED) chips, laser diode (LD) chips, and organic LED (OLED) chips, wherein at least one of the first, second and third light components is emitted from the at least one light emitting chip, wherein the first component of the light spectrum being emitted from the at least one light emitting chip has at least one peak wavelength in a first wavelength range from about 480.1 nm to about 510 nm, the second component has a second wavelength range that is perceived as a green color, and the third component has a third wavelength range that is perceived as a red or orange-red color by human eyes.

2. A display device, comprising:
a liquid crystal display (LCD) panel comprising a plurality of blue color filters, a plurality of green color filters, and a plurality of red color filters; and
a light source configured to provide light to the LCD panel, wherein the light has a spectrum with a first component, a second component and a third component; wherein the first component has at least one peak wavelength in a first wavelength range from about 480.1 nm to about 510 nm, the second component has a second wavelength range that is perceived as a green color, and the third component has a third wavelength range that is perceived as a red or orange-red color by human eyes,
wherein each of the plurality of green color filters is adapted such that they do not transmit the first component of light or transmit a minimal amount of the first component of light so as to prevent a distortion or shift of a CIE (International Commission on Illumination) coordinate of a filtered green light by the first component of light.

3. The display device of claim 2, wherein each of the plurality of green color filters has a transmission of less than or equal to about 5% at a wavelength of about 490 nm, about 10% at a wavelength of about 495 nm, about 30% at a wavelength of about 500 nm, and about 50% at a wavelength of about 510 nm.

4. The display device of claim 2, wherein the transmitted minimal amount of the first component of light is about 10% or less of the first component of light.

5. The display device of claim 2, wherein the light source comprises at least one light emitting chip including at least one of light-emitting diode (LED) chips, laser diode (LD) chips, and organic LED (OLED) chips.

6. A display device, comprising:
a liquid crystal display (LCD) panel comprising a color filter layer having a plurality of blue color filters, a plurality of green color filters and a plurality of red color filters, and a green purifying layer disposed on at least one side of the color filter layer, wherein the green purifying layer is adapted for removing/blocking undesired colors including blue, orange, and/or red colors; and
a light source configured to provide light to the LCD panel, wherein the light has a spectrum with a first component, a second component and a third component; wherein the first component has at least one peak wavelength in a first wavelength range from about 480.1 nm to about 510 nm, the second component has a second wavelength range that is perceived as a green color, and the third component has a third wavelength range that is perceived as a red or orange-red color by human eyes.

7. The display device of claim 6, wherein the green purifying layer is configured such that it only removes or blocking the undesired colors that enter and pass through the plurality of green color filters.

8. The display device of claim 7, wherein the green purifying layer comprises light correcting materials or structures that are only positioned in areas directly above or underneath the plurality of green color filters and are not presented in areas directly above or underneath the plurality of blue filters and the plurality of red color filters.

9. The display device of claim 6, wherein the light source comprises at least one light emitting chip including at least one of light-emitting diode (LED) chips, laser diode (LD) chips, and organic LED (OLED) chips.

10. A display device, comprising:
a substrate, an electrode layer disposed on the substrate, an emissive layer disposed on the electrode layer, a glass film disposed on the emissive layer, and a polarizer film disposed on the glass film or between the emissive layer and the glass film,
wherein the emissive layer comprises light sources that form a matrix of pixels, each pixel comprising subpixels.

11. The display of claim 10, wherein each light source has at least one light emitting chip including at least one of light-emitting diode (LED) chips, laser diode (LD) chips, and organic LED (OLED) chips.

12. The display of claim 10, wherein each pixel contains a light source that provides at least three light components including blue, green, and red light components.

13. The display of claim 12, wherein each pixel contains at least three subpixels with each subpixel having one of a light source that provides one of blue, green, and red light.

14. The display of claim 12, wherein the blue component of the light source has a wavelength ranging from about 430 nm to about 510 nm, with its peak wavelength ranging from about 470 nm to about 500 nm.

15. The display of claim 12, wherein the blue component of the light source has a wavelength ranging from 430 nm to 510 nm, with at least one peak wavelength ranging from about 430 nm to about 470 nm and one peak wavelength ranging from about 470 nm to about 500 nm.

16. The display of claim 10, wherein each pixel contains four subpixels with each subpixel having one of the light sources that provides one of dark blue, light blue, green, and red light, wherein the light blue light source has its peak wavelength ranging from about 470 nm to about 500 nm.
